(19) United States
(12) Patent Application Publication
(10) Pub. No.: US 2018/0301588 A1
(43) Pub. Date: Oct. 18, 2018

(54) IMAGE CAPTURING MODULE AND MANUFACTURING METHOD THEREOF

(71) Applicant: Gingy Technology Inc., Hsinchu City (TW)

(72) Inventor: Kuo-Liang You, Hsinchu City (TW)

(73) Assignee: Gingy Technology Inc., Hsinchu City (TW)

(21) Appl. No.: 15/892,390

(22) Filed: Feb. 8, 2018

Related U.S. Application Data
(60) Provisional application No. 62/486,954, filed on Apr. 18, 2017.

(30) Foreign Application Priority Data
Nov. 20, 2017 (CN) 201711158624.6

(51) Int. Cl. H01L 31/16; H01L 31/02; H01L 25/16; H01L 23/538; G06K 9/00

(52) U.S. Cl. CPC H01L 31/16; H01L 31/02002; H01L 25/165; G06K 9/00087; H01L 23/5383; H01L 23/5386; H01L 25/167

(57) ABSTRACT

An image capturing module including a light emitting element, a sensing element, and a circuit substrate is provided. The circuit substrate includes a substrate, a plurality of conductive plugs, a first wiring layer, and a second wiring layer. The substrate has a first through hole, a second through hole, and a plurality of third through holes. The light emitting element is disposed in the first through hole. The sensing element is disposed in the second through hole. The conductive plugs are disposed in the third through holes. The first wiring layer is disposed on a first surface of the substrate. The second wiring layer is disposed on a second surface of the substrate opposite to the first surface. The second wiring layer is electrically connected to the first wiring layer through the conductive plugs. A manufacturing method of the image capturing module is also provided.

### CROSS-REFERENCE TO RELATED APPLICATION

This application claims the priority benefits of U.S. provisional application Ser. No. 62/486,954, filed on Apr. 18, 2017, and China application serial no. 201711158624.6, filed on Nov. 20, 2017. The entirety of each of the above-mentioned patent applications is hereby incorporated by reference herein and made a part of this specification.

### BACKGROUND OF THE DISCLOSURE

### Field of the Disclosure

The disclosure is related to an optical module and a manufacturing method thereof, and particularly to an image capturing module and a manufacturing method thereof.

### Description of Related Art

Types of biometric identification include face recognition, voice recognition, iris recognition, retina recognition, palm print recognition and fingerprint recognition. Biometric identification devices may be categorized into optical, capacitive, ultrasound and thermo-sensitive techniques according to the sensing method. Known optical biometric identification devices have become one of the mainstream of biometric identification technology. Therefore, persons skilled in the art have been working on how to improve competitiveness of the optical biometric identification device developed by their companies.

### SUMMARY OF THE DISCLOSURE

The disclosure provides an image capturing module with thin thickness and good identification performance.

The disclosure provides a manufacturing method of an image capturing module, which is capable of manufacturing an image capturing module with thin thickness and good identification performance.

An image capturing module of the disclosure includes a light emitting element, a sensing element and a circuit substrate. The circuit substrate includes a substrate, a plurality of conductive plugs, a first wiring layer and a second wiring layer. The substrate has a first through hole, a second through hole and a plurality of third through holes. The light emitting element is disposed in the first through hole. The sensing element is disposed in the second through hole. The plurality of conductive plugs are disposed in the plurality of third through holes. The first wiring layer is disposed on a first surface of the substrate. The second wiring layer is disposed on a second surface of the substrate opposite to the first surface. The second wiring layer is electrically connected to the first wiring layer via the plurality of conductive plugs.

A manufacturing method of an image capturing module of the disclosure includes the following steps. A first through hole, a second through hole and a plurality of conductive plugs are formed in a substrate, wherein the conductive plugs penetrate through the substrate. A light emitting element is disposed in the first through hole. A sensing element is disposed in the second through hole. A first wiring layer is formed on a first surface of the substrate. A second wiring layer is formed on a second surface of the substrate opposite to the first surface, wherein the second wiring layer is electrically connected to the first wiring layer via the conductive plugs.

According to the above, in the image capturing module in the exemplary embodiment of the disclosure, the light emitting element and the sensing element are disposed in the through holes of the substrate, which facilitates to reduce the overall thickness of the image capturing module. In addition, the through holes are formed in the substrate and the light emitting element and the sensing element are disposed in the through holes of the substrate so that a spacer wall is formed naturally between the light emitting element and the sensing element, which can effectively avoid the optical interference caused by large-angle light beams emitted from the light emitting element directly irradiated on the sensing element, thereby improving the identification performance of the image capturing module. Accordingly, the image capturing module has thin thickness and good identification performance. In addition, a manufacturing method of the image capturing module is also provided.

In order to make the aforementioned features and advantages of the disclosure more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A and FIG. 1B are cross-sectional views of different portions of an image capturing module according to a first exemplary embodiment of the disclosure.

FIG. 1C is schematic a top view of an image capturing module according to the first exemplary embodiment of the disclosure.

FIG. 2A to FIG. 6 are schematic views of a manufacturing process flow of an image capturing module according to the first exemplary embodiment of the disclosure.

FIG. 7A is a cross-sectional view of an image capturing module according to a second exemplary embodiment of the disclosure.

FIG. 7B is a schematic top view of an image capturing module according to a second exemplary embodiment of the disclosure.

### DESCRIPTION OF EMBODIMENTS

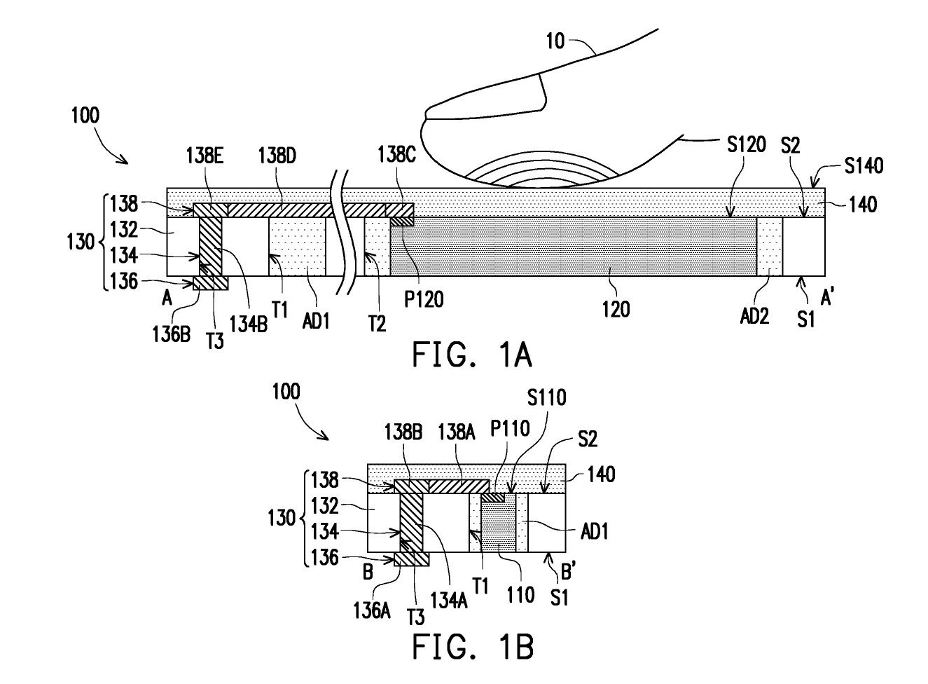

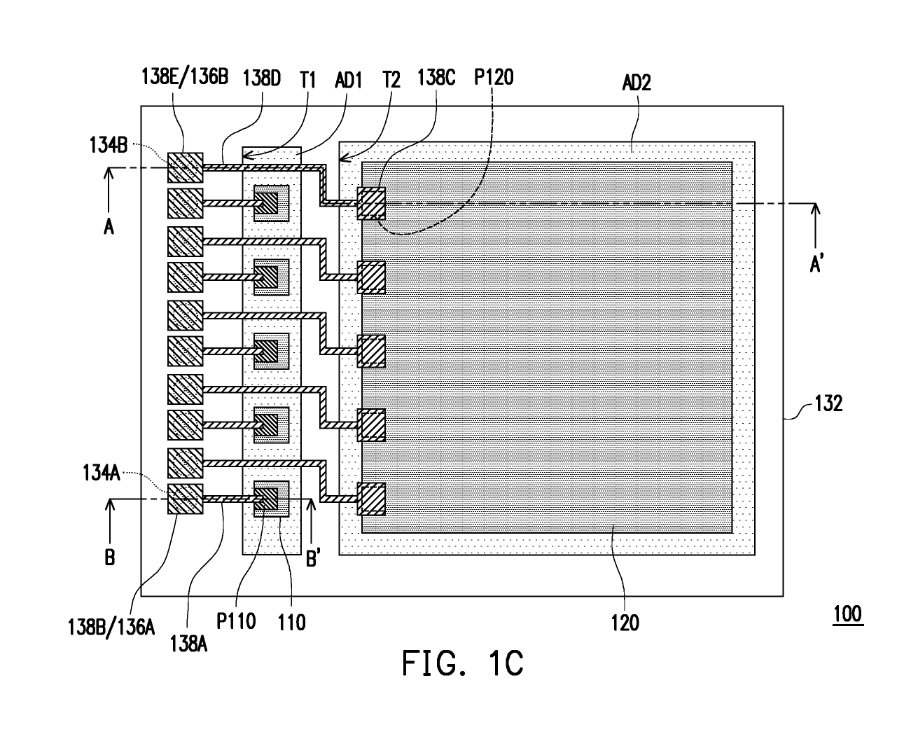

FIG. 1A and FIG. 1B are cross-sectional views of different portions of an image capturing module according to a first exemplary embodiment of the disclosure. FIG. 1C is a schematic top view of an image capturing module according to the first exemplary embodiment of the disclosure. Please refer to FIG. 1A for the cross-sectional view of FIG. 1C taken along line A-A′. Please refer to FIG. 1B for the cross-sectional view of FIG. 1C taken along line B-B′. FIG. 1C does not show a transparent protecting layer in FIG. 1A in order to show the relative configuration relationship of the elements underneath clearly.

Referring to FIG. 1A to FIG. 1C, an image capturing module 100 in the first exemplary embodiment is adapted to capture a biological feature of a test object 10 that is pressed on the image capturing module 100. In the exemplary embodiment, the test object 10 is, for example, a finger, and the biological feature is, for example, a fingerprint or a vein, which should not be construed as a limitation to the disclosure. In another exemplary embodiment, the test object 10 may be a palm and the biological feature may be a palm print.

The image capturing module 100 includes a light emitting element 110, a sensing element 120 and a circuit substrate 130.

The light emitting element 110 provides a light beam (no shown) irradiated on the test object 10. Depending on different needs, the image capturing module 100 may include one or more light emitting elements 110. In the exemplary embodiment, the image capturing module 100 includes a plurality of light emitting elements 110 (FIG. 1C shows five light emitting elements 110), and the plurality of light emitting elements 110 are arranged on the same side of the sensing element 120. However, the number of the light emitting element 110 and the relative configuration relationship of the light emitting element 110 and the sensing element 120 may be changed depending on the need without being limited to the illustration shown in FIG. 1C.

The plurality of light emitting elements 110 may include light emitting diodes, laser diodes or a combination thereof. Correspondingly, the light beam may include a visible light, an invisible light or a combination thereof. The invisible light may be an infrared light, which should not be construed as a limitation to the disclosure.

The sensing element 120 receives a portion of the light beam that is reflected by the test object 10 (i.e., the reflected light beam with fingerprint pattern information) to identify the biological feature of the test object 10. The sensing element 120 may be a charge coupled device (CCD), a complementary metal-oxide semiconductor (CMOS) or other suitable type of image sensing element.

In an exemplary embodiment, the sensing element 120 may be integrated with a pulse-width modulation circuit. The pulse-width modulation circuit controls the light emitting time of the plurality of light emitting elements 110 and the image capturing time of the sensing element 120 so that the light emitting time of the plurality of light emitting elements 110 and the imaging capturing time of the sensing element 120 are synchronized, thereby achieving the effect of precise control, which should not be construed as a limitation to the disclosure.

The circuit substrate 130 includes a substrate 132, a plurality of conductive plugs 134, a first wiring layer 136 and a second wiring layer 138.

The substrate 132 may be a single-layer board or a multi-layer board. In addition, the substrate 132 may have a circuit. For example, the substrate 132 may be a printed circuit board (PCB), a flexible printed circuit board (FPCB), a glass carrier having a circuit or a ceramic substrate having a circuit, which should not be construed as a limitation to the disclosure. In an exemplary embodiment, the substrate 132 may be a transparent substrate without circuit.

The substrate 132 has a first through hole T1, a second through hole T2 and a plurality of third through holes T3. The plurality of light emitting elements 110 are disposed in the first through hole T1. The sensing element 120 is disposed in the second through hole T2. The plurality of conductive plugs 134 are disposed in the plurality of third through holes T3. In the exemplary embodiment, the image capturing module 100 further includes a first adhesive layer AD1 and a second adhesive layer AD2. The first adhesive layer AD1 is disposed in the first through hole T1, and the light emitting element 110 is fixed in the first through hole T1 of the substrate 132 via the first adhesive layer AD1. In addition, the second adhesive layer AD2 is disposed in the second through hole T2, and the sensing element 120 is fixed in the second through hole T2 of the substrate 132 via the second adhesive layer AD2. In an exemplary embodiment, a mechanical means or a fastening structure for fixing may be used to replace at least one of the first adhesive layer AD1 and the second adhesive layer AD2.

The first wiring layer 136 is disposed on a first surface S1 of the substrate 132. The second wiring layer 138 is disposed on a second surface S2 of the substrate 132, and the second surface S2 is opposite to the first surface S1. In other words, the first wiring layer 136 and the second wiring layer 138 are located on the two opposite surfaces of the substrate 132.

In the exemplary embodiment, a conductive pad P110 of each of light emitting elements 110 and a light emitting surface S110 of each of light emitting elements 110 are on the same side of the light emitting element 110 and disposed to be adjacent to the second surface S2. In addition, a plurality of conductive pads P120 of the sensing element 120 and a sensing surface S120 of the sensing element 120 are disposed on the same side of the sensing element 120 and disposed to be adjacent to the second surface S2. Additionally, the light emitting surface S110 of each of the light emitting elements 110, the sensing surface S120 of the sensing element 120 and the second surface S2 of the substrate 132 are on the same plane, which should not be construed as a limitation to the disclosure. Depending on different needs, the light emitting surface S110 of each of the light emitting elements 110 may be higher or lower than the second surface S2 of the substrate 132. Moreover, the sensing surface S120 of the sensing element 120 may be higher or lower than the second surface S2 of the substrate 132.

The second wiring layer 138 is electrically connected to the first wiring layer 136 via the plurality of conductive plugs 134. Moreover, the second wiring layer 138 is electrically connected to the conductive pad P110 of each of the light emitting elements 110 and the plurality of conductive pads P120 of the sensing element 120. Therefore, each of the light emitting elements 110 may be electrically connected to the first wiring layer 136 via the second wiring layer 138 and a first conductive plug 134A of the plurality of conductive plugs 134. Furthermore, the sensing element 120 may be electrically connected to the first wiring layer 136 via the second wiring layer 138 and a second conductive plug 134B of the plurality of conductive plugs 134.

Specifically, the second wiring layer 138 may include a plurality of wirings 138A electrically connected to the plurality of conductive pads P110 of the plurality of light emitting elements 110, a plurality of conductive pads 138B electrically connected to the plurality of wirings 138A, a plurality of conductive pads 138C electrically connected to the plurality of conductive pads P120 of the sensing element 120, a plurality of wirings 138D electrically connected to the plurality of conductive pads 138C, a plurality of conductive pads 138E electrically connected to the plurality of wirings 138D and other wirings and conductive pads that are not shown. The first wiring layer 136 may include a plurality of conductive pads 136A electrically connected to the plurality of first conductive plugs 134A and a plurality of conductive pads 136B electrically connected to the plurality of second conductive plugs 134B. Each of the light emitting elements 110 may be electrically connected to a corresponding conductive pad 136A via one of the wirings 138A, one of the conductive pads 138B and one of the first conductive plugs 134A. Additionally, the sensing element 120 may be electrically connected to a corresponding conducive pad 136B via one of the conductive pads 138C, one of the wirings 138D, one of the conductive pads 138E and one of the second conductive plugs 134B.

Depending on different needs, the image capturing module 100 may further include other layers. For example, the image capturing module 100 may further include a transparent protecting layer 140. The transparent protecting layer 140 is disposed on the second surface S2 and covers the plurality of light emitting elements 110, the sensing element 120 and the second wiring layer 138. In addition to providing protection function (e.g., scratch-resistance function), the transparent protecting layer 140 may further be formed into a flat surface S140 to be pressed by the test object 10 or to carry other element (e.g., transparent protecting cover). Accordingly, the image capturing module 100 can be combined with other electronic device or element more easily. For example, the transparent protecting layer 140 may be cured by a transparent gel, which should not be construed as a limitation to the disclosure. In one exemplary embodiment, the transparent protecting layer 140 may be omitted, and a transparent protecting cover can be further disposed on the substrate 132, and the protecting cover is configured to cover the substrate 132, the sensing element 120 and the plurality of light emitting elements 110, wherein the substrate 132 and the protecting cover may be fixed via an adhesive layer, a mechanical means or a fastening structure.

As compared with the configuration that the plurality of light emitting elements 110 and the sensing element 120 are disposed on the substrate and a wire bonding process is conducted to make the plurality of light emitting elements 110 and the sensing element 120 to be electrically connected with the substrate 132, in the exemplary embodiment, a plurality of through holes (including the first through hole T1, the second through hole T2 and the plurality of third through holes T3) are formed in the substrate 132 to dispose the plurality of light emitting elements 110, the sensing element 120 and the conductive plugs 134 in the through holes of the substrate 132, and required circuit layers are formed on the two opposite surfaces of the substrate 132, which facilitates to reduce the overall thickness of the image capturing module 100. Moreover, through holes are formed in the substrate 132, and the plurality of light emitting elements 110 and the sensing element 120 are disposed in the through holes of the substrate 132 so that a spacer wall can be formed naturally between the sensing element 120 and each of the light emitting elements 110. In this manner, the optical interference caused by the large-angle light beam emitted from each of the light emitting elements 110 directly irradiated on the sensing element 120 can be effectively avoided without the need of disposing an additional light shielding element between the sensing element 120 and each of the light emitting elements 110, thereby improving identification performance of the image capturing module 100. Accordingly, the image capturing module 100 has thin thickness and good identification performance.

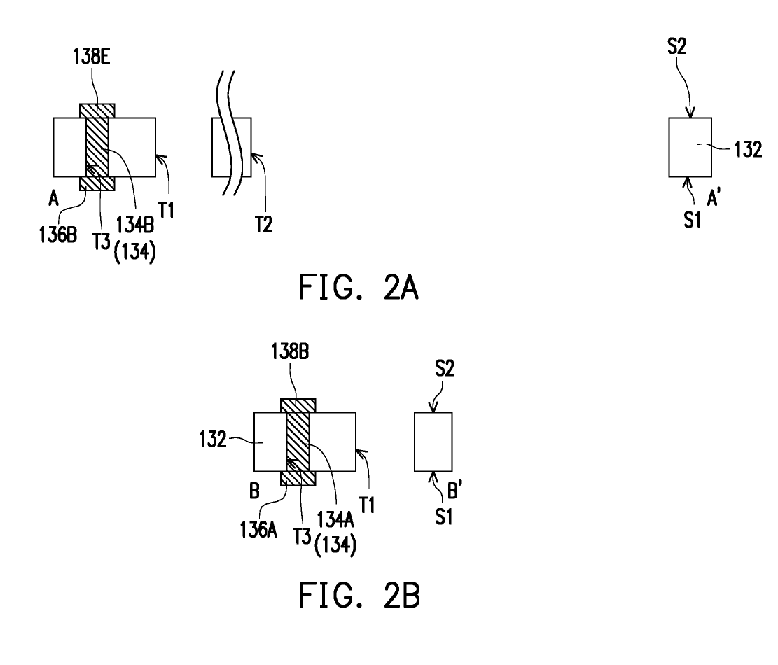

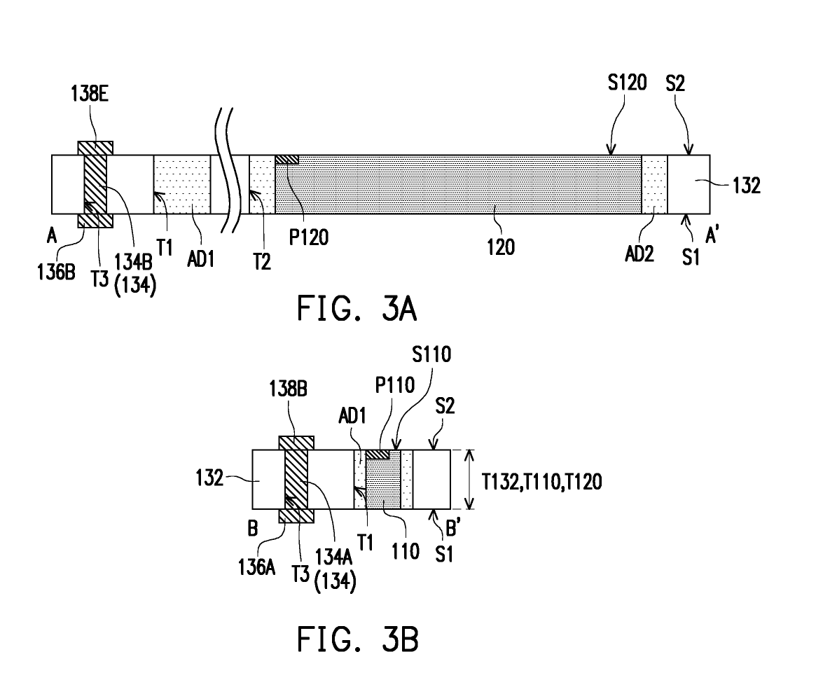

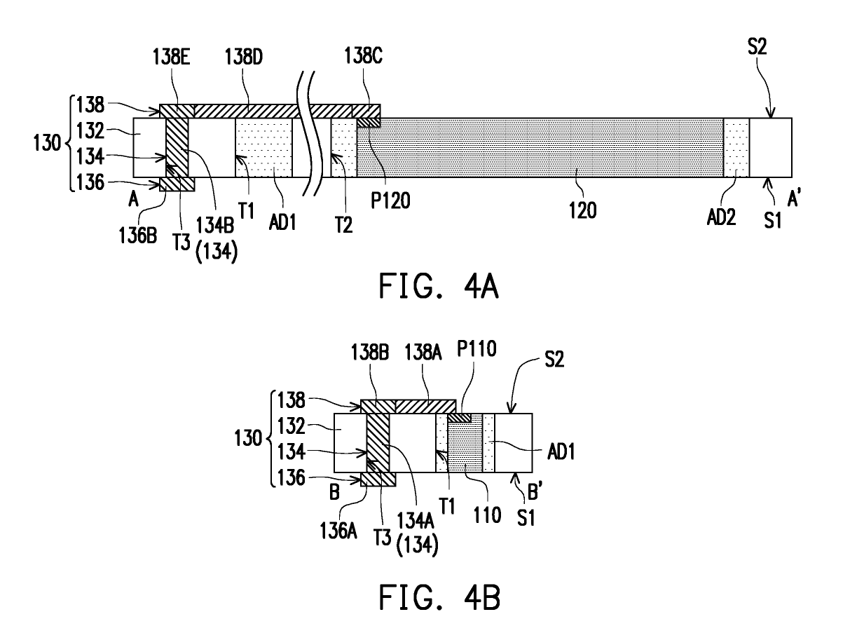

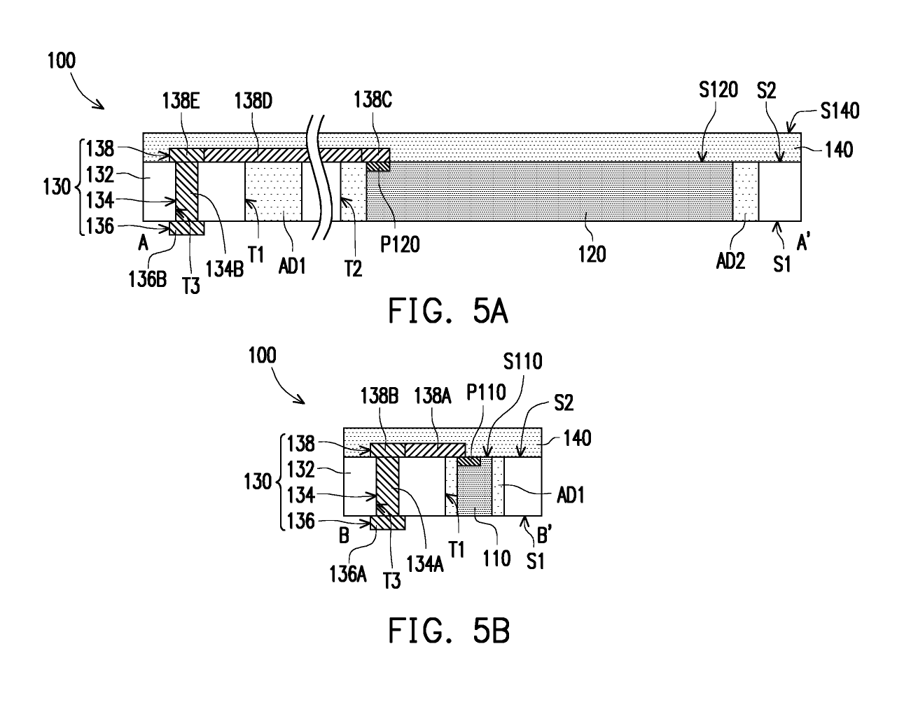

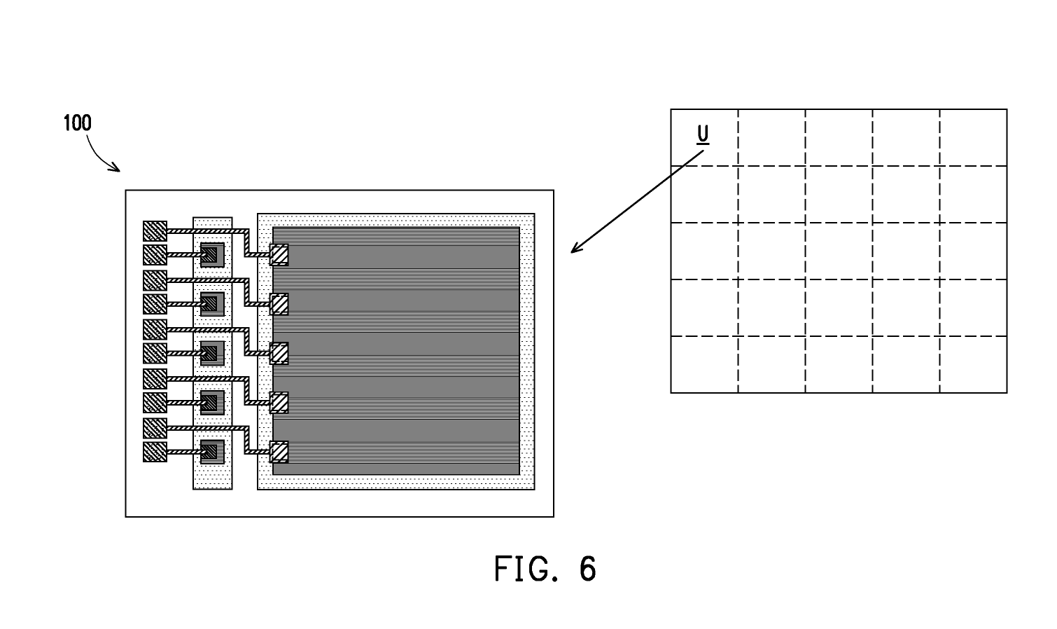

FIG. 2A to FIG. 6 are schematic views of a manufacturing process flow of an image capturing module according to the first exemplary embodiment of the disclosure. However, the manufacturing method of the image capturing module 100 in FIG. 1A to FIG. 1C is not limited to the illustration shown in FIG. 2A to FIG. 6. Also, it should be mentioned that FIG. 2A, FIG. 3A, FIG. 4A and FIG. 5A illustrate the manufacturing process corresponding to the cross-section of FIG. 1A. FIG. 2B, FIG. 3B, FIG. 4B and FIG. 5B illustrate the manufacturing process corresponding to the cross-section of FIG. 1B. FIG. 6 is a schematic top view which illustrates a plurality of image capturing modules formed via a cutting step.

Referring to FIG. 2A and FIG. 2B, the substrate 132 is provided, and the first through hole T1 for disposing the light emitting element, the second through hole T2 for disposing the sensing element and the plurality of conductive plugs 134 (including the first conductive plug 134A and the second conductive plug 134B) penetrating through the substrate 132 are formed in the substrate 132. The method for forming the plurality of conductive plugs 134 may include forming the plurality of third through holes T3 for disposing the plurality of conductive plugs in the substrate 132, and filling a conductive material into the plurality of third through holes T3. After forming the plurality of conductive plugs 134, the conductive pad 136A that is disposed on the first surface S1 of the substrate 132 and electrically connected to the first conductive plug 134A, the conductive pad 138B disposed on the second surface S2 of the substrate 132 and electrically connected to the first conductive plug 134A, the conductive pad 136B disposed on the first surface S1 of the substrate 132 and electrically connected to the second conductive plug 134B and the conductive pad 138E disposed on the second surface S2 of the substrate 132 and electrically connected to the second conductive plug 134B may be further formed, which should not be construed as a limitation to the disclosure.

Referring to FIG. 3A and FIG. 3B, the light emitting element 110 is disposed in the first through hole T1. In the exemplary embodiment, the method for disposing the light emitting element 110 in the first through hole T1 includes fixing the light emitting element 110 in the first through hole T1 of the substrate 132 via the first adhesive layer AD1. For example, the conductive pad P110 of the light emitting element 110 may be disposed to be adjacent to the second surface S2 of the substrate 132, and the first adhesive layer AD1 is filled in the first through hole T1 via an underfill method such that the light emitting element 110 is fixed in the first through hole T1 of the substrate 132 via the first adhesive layer AD1, which should not be construed as a limitation to the disclosure. In another exemplary embodiment, the light emitting element 110 may be fixed in the first through hole T1 of the substrate 132 via other means (e.g., via a mechanical means or a fastening structure) to omit the first adhesive layer AD1.

In addition, prior to disposing the light emitting element 110 in the first though hole T1, the light emitting element 110 may be polished first via a polishing process so that a thickness T110 of the light emitting element 110 is equal to a thickness T132 of the substrate 132. In this manner, after the light emitting element 110 is disposed in the first through hole T1, the light emitting surface S110 of the light emitting element 110 and the second surface S2 of the substrate 132 may be located on the same plane, which should not be construed as a limitation to the disclosure. Depending on different needs, the light emitting surface S110 of the light emitting element 110 may be higher or lower than the second surface S2 of the substrate 132. Alternatively, in the condition that the thickness T110 of the light emitting element 110 is the predetermined thickness, the polishing process may be omitted.

After the light emitting element 110 is disposed in the first through hole T1, the sensing element 120 may be disposed in the second through hole T2. In the exemplary embodiment, the method of disposing the sensing element 120 in the second through hole T2 includes fixing the sensing element 120 in the second through hole T2 of the substrate 132 via the second adhesive layer AD2. For example, the conductive pad P120 of the sensing element 120 may be disposed to be adjacent to the second surface S2 of the substrate 132, and the second adhesive layer AD2 is filled in the second through hole T2 via an underfill method such that the sensing element 120 is fixed in the second through hole T2 of the substrate 132 via the second adhesive layer AD2, which should not be construed a limitation to the disclosure. In another exemplary embodiment, the sensing element 120 may be fixed in the second through hole T2 of the substrate 132 via other means (e.g., via a mechanical means or a fastening structure) to omit the second adhesive layer AD2.

Moreover, prior to disposing the sensing element 120 in the second through hole T2, the sensing element 120 may be polished first via a polishing process so that a thickness T120 of the sensing element 120 is equal to the thickness T132 of the substrate 132. In this manner, after the sensing element 120 is disposed in the second through hole T2, the sensing surface S120 of the sensing element 120 and the second surface S2 of the substrate 132 can be located on the same plane, which should not be construed a limitation to the disclosure. Depending on different needs, the sensing surface S120 of the sensing element 120 may be higher or lower than the second surface S2 of the substrate 132. Alternatively, in the condition that the thickness T120 of the sensing element 120 is the predetermined thickness, the polishing process may be omitted.

In one exemplary embodiment, the sensing element 120 may be disposed in the second through hole T2 first, and the light emitting element 110 is disposed in the first through hole T1 thereafter.

Referring to FIG. 4A and FIG. 4B, other required circuit is formed on the first surface S1 of the substrate 132 to complete fabrication of the first wiring layer 136. In addition, other required circuit is formed on the second surface S2 of the substrate 132 to complete fabrication of the second wiring layer 138, wherein the second wiring layer 138 is electrically connected to the first wiring layer 136 via the plurality of conductive plugs 134. The first wiring layer 136 and the second wiring layer 138 are respective patterned conducive layers, and the elements included therein are described in the previous corresponding paragraphs; thus no further descriptions are incorporated herein. In the steps illustrated in FIG. 4A and FIG. 4B, the method for forming the circuit may include at least one of an exposure and development process, a plating process and a printing process, which should not be construed as a limitation to the disclosure.

In an exemplary embodiment, the conductive pad 136A, the conductive pad 138B, the conductive pad 136B and the conducive pad 138E formed in the steps illustrated in FIG. 2A and FIG. 2B may be manufactured through the steps illustrated in FIG. 4A and FIG. 4B.

Referring to FIG. 5A and FIG. 5B, the transparent protecting layer 140 is disposed on the second surface S2, wherein the transparent protecting layer 140 covers the light emitting element 110, the sensing element 120 and the second wiring layer 138. In the exemplary embodiment, the method for forming the transparent protecting layer 140 is, for example, by forming a transparent material on the second surface S2 using a coating method, and the transparent material is cured via a thermal curing process or a photo-curing process, which should not be construed as a limitation to the disclosure.

Through the above-mentioned steps, the image capturing module 100 is preliminarily completed. In one exemplary embodiment, as shown in FIG. 6, a plurality of image capturing units U (the plurality of light emitting elements 110 and the plurality of sensing elements 120 are disposed in the substrate 132, and the required circuit and transparent protecting layer are formed) may be manufactured simultaneously, and a plurality of image capturing modules 100 are formed via a cutting process (along the dashed line in FIG. 6).

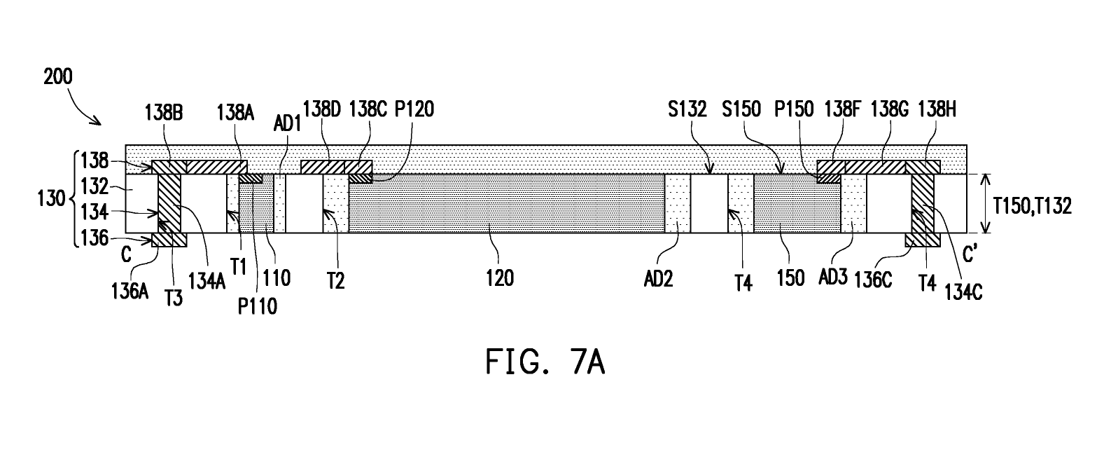

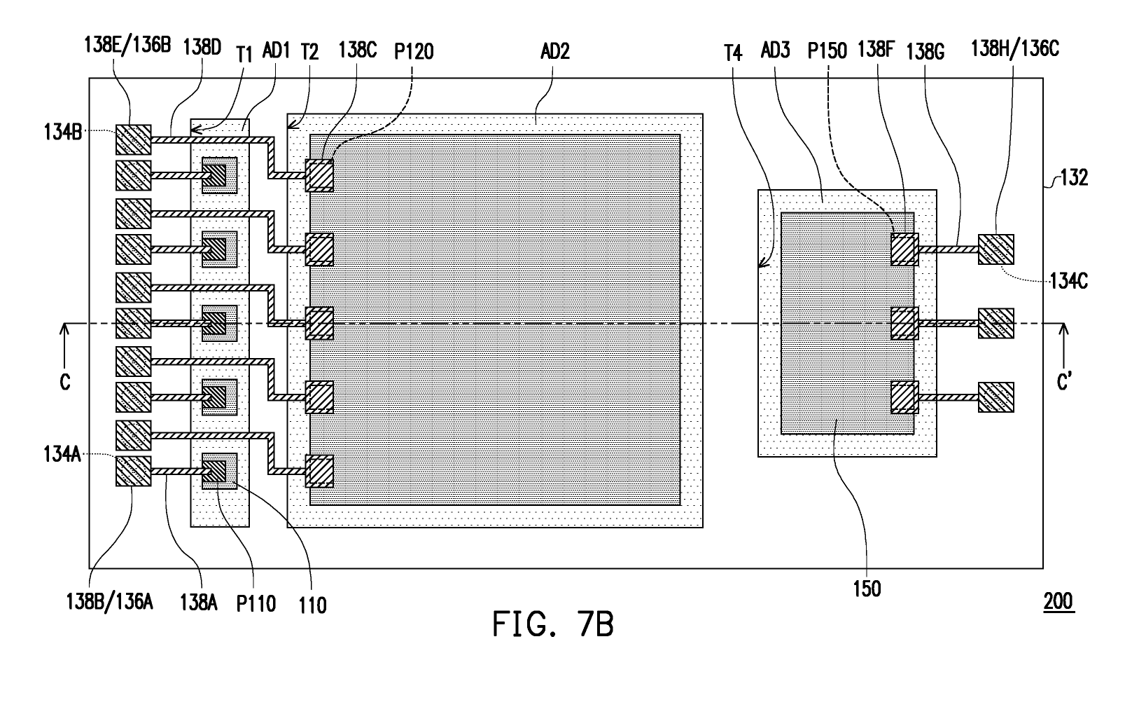

FIG. 7A is a cross-sectional view of an image capturing module according to a second exemplary embodiment of the disclosure. FIG. 7B is a schematic top view of an image capturing module according to the second exemplary embodiment of the disclosure. Please refer to FIG. 7A for the cross-sectional view of FIG. 7B taken along line C-C′. FIG. 7B does not show the transparent protecting layer in FIG. 7A in order to show the relative configuration relationship of the elements underneath clearly. Referring to FIG. 7A and FIG. 7B, an image capturing module 200 in the second exemplary embodiment is similar to the image capturing module 100 shown in FIG. 1A and FIG. 1B, wherein the same elements are denoted by the same reference numerals. Descriptions regarding the material, relative configuration relationship, manufacturing method and effect of the elements are not incorporated herein. The main differences between the image capturing module 200 and the image capturing module 100 are described as follows.

In the image capturing module 200, the substrate 132 further has a fourth through hole T4, and the image capturing module 200 further includes a micro-controller 150. The micro-controller 150 is disposed in the fourth through hole T4. In the exemplary embodiment, the sensing element 120 is disposed between the micro-controller 150 and the plurality of light emitting elements 110. However, the relative configuration relationship of the above-mentioned elements may be changed denying on the need without being limited to the illustration shown in FIG. 7B.

In the exemplary embodiment, the method for disposing the micro-controller 150 in the fourth through hole T4 may include disposing the micro-controller 150 in the fourth through hole T4 via a third adhesive layer AD3. Specifically, the image capturing module 200 may further include a third adhesive layer AD3. The third adhesive layer AD3 is disposed in the fourth through hole T4, and the micro-controller 150 is fixed in the fourth through hole T4 of the substrate 132 via the third adhesive layer AD3. In one exemplary embodiment, the micro-controller 150 may be fixed in the fourth through hole T4 of the substrate 132 via a mechanical means or a fastening structure to omit the third adhesive layer AD3.

In addition, a conductive pad P150 of the micro-controller 150 may be disposed to be adjacent to the second surface S2, and the micro-controller 150 may be electrically connected to the first wiring layer 136 via the second wiring layer 138 and the conductive plugs 134. Specifically, the second wiring layer 138 may further include a plurality of conductive pads 138F electrically connected to the plurality of conductive pads P150 of the micro-controller 150, a plurality of wirings 138G electrically connected to the plurality of conductive pads 138F and a plurality of conductive pads 138H electrically connected to the plurality of wirings 138G. The conductive plugs 134 may further include a plurality of third conductive plugs 134C electrically connected to the plurality of conductive pads 138H. The first wiring layer 136 may further include a plurality of conductive pads 136C electrically connected to the plurality of third conductive plugs 134C. Each of the conducive pads P150 of the micro-controller 150 may be electrically connected to a corresponding conductive pad 136C via one of the conductive pad 138F, one of the wirings 138G, one of the conductive pads 138H and one of the third conductive plugs 134C.

In the exemplary embodiment, prior to disposing the micro-controller 150 in the fourth through hole T4, the micro-controller 150 may be polished first via a polishing process so that a thickness T150 of the micro-controller 150 is equal to the thickness T132 of the substrate 132. In this manner, after the micro-controller 150 is disposed in the fourth through hole T4, a surface S150 of the controller 150 adjacent to the second surface S2 and the second surface S2 of the substrate 132 may be located on the same plane, which should not be construed as a limitation to the disclosure. Depending on different needs, the surface S150 of the micro-controller 150 may be higher or lower than the second surface S2 of the substrate 132. Alternatively, in the condition that the thickness T150 of the micro-controller 150 is the predetermined thickness, the polishing process may be omitted.

As compared with the configuration that the plurality of light emitting elements 110, the sensing element 120 and the micro-controller 150 are disposed on the substrate 132 and a wire bonding process is conducted so that the plurality of light emitting elements 110, the sensing element 120 and the micro-controller 150 are electrically connected to the substrate 132, in the exemplary embodiment, the plurality of through holes (including the first through hole T1, the second through hole T2, the plurality of third through holes and the fourth through hole T4) are formed in the substrate 132, the plurality of light emitting elements 110, the sensing element 120, the conductive plug 134 and the micro-controller 150 are disposed in the through holes of the substrate 132 and required circuit layers are formed on two opposite surfaces of the substrate 132, which facilitates to reduce the overall thickness of the image capturing module 200.

In summary, in the image capturing module described in the exemplary embodiment of the disclosure, the light emitting elements and the sensing element are disposed in the through holes of the substrate, which facilitates to reduce the overall thickness of the image capturing module. In addition, the through holes are formed in the substrate and the light emitting element and the sensing element are disposed in the through holes of the substrate so that a spacer wall is formed naturally between the light emitting element and the sensing element, which can effectively avoid the optical interference caused by large-angle light beams emitted from the light emitting elements directly irradiated on the sensing element, thereby improving the identification performance of the image capturing modules. In this manner, the image capturing module has thin thickness and good identification performance. In one exemplary embodiment, the transparent protecting layer may be formed into the flat surface to be pressed by the test object or to carry other element (e.g., transparent protecting cover). In this manner, a structure with full plane as the pressing surface can be achieved so that the image capturing module can be combined with other electronic device more easily. In addition, in the manufacturing method of the image capturing module described in the exemplary embodiment of the disclosure, the light emitting elements and the sensing element can be firmly fixed in the through holes of the substrate via the adhesive layers to avoid the problem of displacement of elements or wiring breakage, thereby improving yield rate and production capacity of the image capturing module. In addition, since there is no need to form an additional light shielding element between the light emitting elements and the sensing element, the manufacturing time and cost can be saved.

Although the disclosure has been disclosed by the above embodiments, the embodiments are not intended to limit the disclosure. It will be apparent to those skilled in the art that various modifications and variations can be made to the structure of the disclosure without departing from the scope or spirit of the disclosure. Therefore, the protecting range of the disclosure falls in the appended claims.

What is claimed is:

1. An image capturing module, comprising:
a light emitting element;
a sensing element; and
a circuit substrate, comprising a substrate, a plurality of conductive plugs, a first wiring layer and a second wiring layer, wherein the substrate has a first through hole, a second through hole and a plurality of third through holes, the light emitting element is disposed in the first through hole, the sensing element is disposed in the second through hole, the conducive plugs are disposed in the third through holes, the first wiring layer is disposed on a first surface of the substrate, the second wiring layer is disposed on a second surface of the substrate opposite to the first surface, and the second wiring layer is electrically connected to the first wiring layer via the conductive plugs.

2. The image capturing module according to claim 1, wherein the substrate is a multi-layer board.

3. The image capturing module according to claim 1, wherein a light emitting surface of the light emitting element and the second surface are located on a same plane.

4. The image capturing module according to claim 1, wherein a sensing surface of the sensing element and the second surface are located on a same plane.

5. The image capturing module according to claim 1, further comprising:
a first adhesive layer, disposed in the first through hole, and the light emitting element is fixed in the first through hole of the substrate via the first adhesive layer.

6. The image capturing module according to claim 1, further comprising:
a second adhesive layer, disposed in the second through hole, and the sensing element is fixed in the second through hole of the substrate via the second adhesive layer.

7. The image capturing module according to claim 1, wherein a conductive pad of the light emitting element and a light emitting surface of the light emitting element are located on a same side of the light emitting element and disposed to be adjacent to the second surface, and the light emitting element is electrically connected to the first wiring layer via the second wiring layer and a first conductive plug of the conductive plugs, a conductive pad of the sensing element and a sensing surface of the sensing element are located on a same side of the sensing element and disposed to be adjacent to the second surface, and the sensing element is electrically connected to the first wiring layer via the second wiring layer and a second conducive plug of the conductive plugs.

8. The image capturing module according to claim 1, further comprising:
a transparent protecting layer, disposed on the second surface and covering the light emitting element, the sensing element and the second wiring layer.

9. The image capturing module according to claim 7, further comprising:
a transparent protecting layer, disposed on the second surface and covering the light emitting element, the sensing element and the second wiring layer.

10. The image capturing module according to claim 1, wherein the substrate further has a fourth through hole, and the image capturing module further comprises:
a micro-controller, disposed in the fourth through hole.

11. The image capturing module according to claim 10, wherein a thickness of the micro-controller is equal to a thickness of the substrate.

12. A manufacturing method of an image capturing module, comprising:
forming a first through hole, a second through hole and a plurality of conductive plugs in the substrate, wherein the conductive plugs penetrate through the substrate;
disposing a light emitting element in the first through hole;
disposing a sensing element in the second through hole;
forming a first wiring layer on a first surface of the substrate; and
forming a second wiring layer on a second surface of the substrate opposite to the first surface, wherein the second wiring layer is electrically connected to the first wiring layer via the conductive plugs.

13. The manufacturing method of the image capturing module according to claim 12, wherein prior to disposing the light emitting element in the first through hole, the manufacturing method of the image capturing module further comprises:
making a thickness of the light emitting element to be equal to a thickness of the substrate.

14. The manufacturing method of the image capturing module according to claim 12, wherein prior to disposing the sensing element in the second through hole, the manufacturing method of the image capturing module further comprises:
making a thickness of the sensing element to be equal to a thickness of the substrate.

15. The manufacturing method of the image capturing module according to claim 12, wherein a method of disposing the light emitting element in the first through hole comprises fixing the light emitting element in the first through hole of the substrate via a first adhesive layer.

16. The manufacturing method of the image capturing module according to claim 12, wherein a method of disposing the sensing element in the second through hole comprises fixing the sensing element in the second through hole of the substrate via a second adhesive layer.

17. The manufacturing method of the image capturing module according to claim 12, wherein a method of disposing the light emitting element in the first through hole and disposing the sensing element in the second through hole comprises disposing a conductive pad of the light emitting element and a conductive pad of the sensing element to be adjacent to the second surface,
wherein after the second wiring layer is formed on the second surface, the light emitting element and the sensing element are electrically connected to the first wiring layer via the second wiring layer and the conductive plugs.

18. The manufacturing method of the image capturing module according to claim 12, further comprising:
disposing a transparent protecting layer on the second surface, wherein the transparent protecting layer covers the light emitting element, the sensing element and the second wiring layer.

19. The manufacturing method of the image capturing module according to claim 12, further comprising:
forming a fourth through hole in the substrate; and
disposing a micro-controller in the fourth through hole.

20. The manufacturing method of the image capturing module according to claim 19, wherein prior to disposing the micro-controller in the fourth through hole, the manufacturing method of the image capturing module further comprises:
making a thickness of the micro-controller to be equal to a thickness of the substrate.
